(19) United States
(12) Patent Application Publication
(10) Pub. No.: US 2026/0182186 A1
(43) Pub. Date: Jun. 25, 2026

(54) DISPLAY DEVICE

(71) Applicant: LG Display Co., Ltd., Seoul (KR)

(72) Inventors: Hyun-Jik BAE, Paju-si (KR); Jung-Seop YOON, Paju-si (KR)

(73) Assignee: LG Display Co., Ltd., Seoul (KR)

(21) Appl. No.: 19/403,577

(22) Filed: Nov. 28, 2025

(30) Foreign Application Priority Data
Dec. 24, 2024 (KR) 10-2024-0195682

(51) Int. Cl. H10K 59/131; H05K 1/18; H10K 59/121; H10K 59/124; H10K 59/126

(52) U.S. Cl. CPC H10K 59/131; H05K 1/189; H10K 59/1213; H10K 59/124; H10K 59/126; H05K 2201/10128

(57) ABSTRACT

A display device in some examples includes a display panel having a display area and a non-display area positioned outside of the display area, a connection area disposed in the non-display area and a flexible circuit board attached to the non-display area, a data link line disposed in the non-display area and connected to a data line of the display area, and a pad electrode disposed in the non-display area and connected electrically to a signal line of the flexible circuit board. The connection area can include a first area adjacent to the display area and a second area between the first area and an edge of the display panel, and the data link line and the pad electrode are connected to the second area of the connection area.

### CROSS-REFERENCE TO RELATED APPLICATION

This application claims priority under 35 U.S.C. § 119(a) to the Korean Patent Application No. 10-2024-0195682, filed in the Republic of Korea on Dec. 24, 2024, the entire contents of which are hereby expressly incorporated by reference into the present application.

### BACKGROUND

### Technical Field

The present disclosure relates to a display device, and more particularly to, a display device with a minimal bezel area.

### Discussion of the Related Art

As multi-media technologies have advanced over the years, various display devices have been applied in various settings for different purposes. Various display devices such as a liquid crystal display and an organic light-emitting display device have been proposed.

As the display devices have been applied to small mobile electronic apparatuses such as a smart phone or a tablet PC, it is needed to minimize a surface area of a bezel or to implement a bezel-less structure so as to implement a relatively large display area and good appearance in a small area.

### SUMMARY OF THE DISCLOSURE

Accordingly, one or more embodiments of the present disclosure are directed to a display device that substantially obviates one or more of the problems due to the limitations and disadvantages of the related art.

An aspect of the present disclosure is to provide a display device with a minimal bezel area.

Additional features and aspects will be set forth in the description that follows, and in part will be apparent from the description, or can be learned by practice of the disclosed concepts provided herein. Other features and aspects of the disclosed concept can be realized and attained by the structure particularly pointed out in the written description, or derivable therefrom, and the claims hereof as well as the appended drawings.

To achieve these and other aspects of the inventive concepts, as embodied and broadly described, in one aspect, the present disclosure provides a display device that comprises a display panel including a display area and a non-display area positioned outside of the display area; a connection area disposed in the non-display area of the display panel and a flexible circuit board attached to the non-display area; a data link line disposed in the non-display area of the display panel and connected to a data line of the display area; and a pad electrode disposed in the non-display area of the display panel and connected electrically to a signal line of the flexible circuit board, wherein the connection area includes a first area adjacent to the display area and a second area between the first area and an edge of the display panel, and the data link line and the pad electrode are connected to the second area of the connection area.

In one embodiment of the present disclosure, at least a portion of the data link line can be positioned to overlap with the pad electrode. The display device can further include a shielding electrode disposed between the data link line and the pad electrode. The data link line can be connected electrically to the pad electrode through a contact portion.

In another embodiment of the present disclosure, the data link line can comprise a same material as the gate electrode, the shielding electrode can comprise a same material as the source electrode and the drain electrode, and/or the pad electrode can comprise a same material as the connecting pattern.

In another aspect, the present disclosure provides a display device that comprises a display panel including a display area and a non-display area positioned outside of the display area; a flexible circuit board attached to the non-display area of the display panel; a data link line disposed in the non-display area of the display panel and connected to a data line of the display area; and a pad electrode disposed in the non-display area of the display panel and connected electrically to a signal line of the flexible circuit board, wherein the data link line is extended to an inside of the flexible circuit board, and at least a portion of the data link line is positioned to overlap with the pad electrode with an insulating layer between the data link line and the pad electrode.

In one or more embodiments of the present disclosure, the contact portion where the data link line and the pad electrode for the flexible circuit board are connected is arranged in an area adjacent to the edge of the display panel. A portion of the connection area to which the flexible circuit board is attached can be used as an arrangement space for the data link line. The area of the non-display area at the periphery of the display panel can be minimized, and as a result, a narrow bezel can be implemented.

In addition, according to aspects of the present disclosure, as the display device can minimize the screen size in the same area, power consumption can be reduced according to high efficiency, and low power can be implemented.

It is to be understood that both the foregoing general description and the following detailed description are examples and explanatory, and are intended to provide further explanation of the inventive concepts as claimed.

### BRIEF DESCRIPTION OF THE DRAWINGS

The accompanying drawings, which provide a further understanding of the disclosure, are incorporated in and constitute a part of this application, illustrate embodiments of the disclosure and together with the description serve to explain principles of the disclosure.

FIG. 1 illustrates a schematic block diagram of a display device in accordance with one or more embodiments of the present disclosure.

FIG. 2 illustrates a schematic block diagram of a sub-pixel in the display device in accordance with one or more embodiments of the present disclosure.

FIG. 3 illustrates a schematic circuit diagram of a sub-pixel in the display device in accordance with one or more embodiments of the present disclosure.

FIG. 4 illustrates a schematic plane view of a display device in accordance with one or more embodiments of the present disclosure.

FIG. 5 illustrates an enlarged plane view of “A” region in FIG. 4 according to an example of the present disclosure.

FIG. 6A illustrates a schematic display device where a contact portion is positioned on an upper area of a connection area to which a flexible circuit board is attached.

FIG. 6B illustrates a schematic display device where a contact portion is positioned on a lower area of a connection area to which a flexible circuit board is attached in accordance with one or more embodiments of the present disclosure.

FIG. 7 illustrates a schematic cross-sectional view of the display device taken along a line I-I′ in FIG. 4 according to an example of the present disclosure.

FIG. 8A illustrates a schematic cross-sectional view of the display device taken along a line II-II′ in FIG. 5 according to an example of the present disclosure.

FIG. 8B illustrates a schematic cross-sectional view of the display device taken along a line III-III′ in FIG. 5 according to an example of the present disclosure.

### DETAILED DESCRIPTION OF THE EMBODIMENTS

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

Shapes, sizes, ratios, angles, numbers, and the like disclosed in the drawings for describing embodiments of the present disclosure are merely illustrative examples, and thus the present disclosure is not limited to the illustrated examples. The same reference numerals refer to the same components throughout this disclosure unless otherwise specified. Further, in the following description of the present disclosure, where a detailed description of a known related art can unnecessarily obscure the gist of the present disclosure, the detailed description thereof can be omitted herein or can be briefly discussed.

Where terms such as “including,” “having,” “comprising,” and the like are used in this disclosure, other parts can be added unless a more limiting term like “only” is used herein. Further, where a component is expressed as being singular, being plural is included, and vice versa, unless otherwise specified. Further, the term “can” fully encompasses all the meanings and coverages of the term “may.”

In analyzing a component, an error range should be interpreted as being included even where there is no explicit description.

In describing a positional relationship, for example, where a positional relationship of two parts/layers is described using terms such as “over,” “on,” “above,” “below,” “under,” “next to,” or the like, one or more other parts/layers can be provided between the two parts/layers, unless a more limiting term like “immediately” or “directly” is used therewith.

In describing a temporal relationship, for example, where a temporal predecessor relationship is described using terms such as “after,” “subsequent,” “next to,” “prior to,” or the like, unless a more limiting term like “immediately” or “directly” is used, cases that are not continuous or sequential can also be included

Although the terms first, second, and the like can be used to describe various components, these components are not substantially limited by these terms. These terms are used only to refer to one component separately from another component, and may not define any particular order or sequence. Therefore, a first component described below can substantially be a second component, and vice versa, within the technical spirit of the present disclosure.

In describing components of the present disclosure, terms such as first, second, A, B, (a), (b), etc. can be used. These terms are only intended to distinguish the components from other components, and the nature, order, sequence, or numbers of the components are not limited by the terms. When it is described that a component is “connected,” “coupled,” or “connected” to another component, it should be understood that the component can be directly connected or connected to the other component, but that other components can also be “interposed” between each component, or that each component can be “connected,” “coupled,” or “connected” through another component.

Features of various embodiments of the present disclosure can be partially or entirely united or combined with each other, technically various interlocking and driving are possible, and each of the embodiments can be independently implemented with respect to each other or implemented together in a co-dependent relationship.

All the components of each display device according to all embodiments of the present disclosure are operatively coupled and configured.

As used herein, ‘display device’ or ‘display device’ can comprise a narrowly defined display device such as a display module including a display panel and a driving unit for driving the display panel. In addition, the display device can also include a set electronic device or a set apparatus such as a notebook computer, a television, a computer monitor, an automotive display, or other forms of a vehicle, which are complete products (or final products) including a display module, an equipment display, a mobile electronic device such as a smart phone or an electronic pad, and the like.

Therefore, the display device in the present disclosure can include a narrowly defined display device itself such as a display module, and a set apparatus which is an application product or a final consumer device including a display module.

The present disclosure can be applied to various display devices/apparatuses. For example, the disclosure can be applied to an organic light-emitting display device, a liquid crystal display device, an electrophoretic display device, a quantum-dot display device, a micro light-emitting diode (LED) display device, a mini LED display device, etc. For the convenience of explanation, the organic light-emitting display device as an example of the display device can be described. However, the present disclosure is not limited to the organic light-emitting display device.

Reference will now be made in detail to aspects of the disclosure, examples of which are illustrated in the accompanying drawings. Wherever possible, the same reference numbers will be used throughout the drawings to refer to the same or like parts.

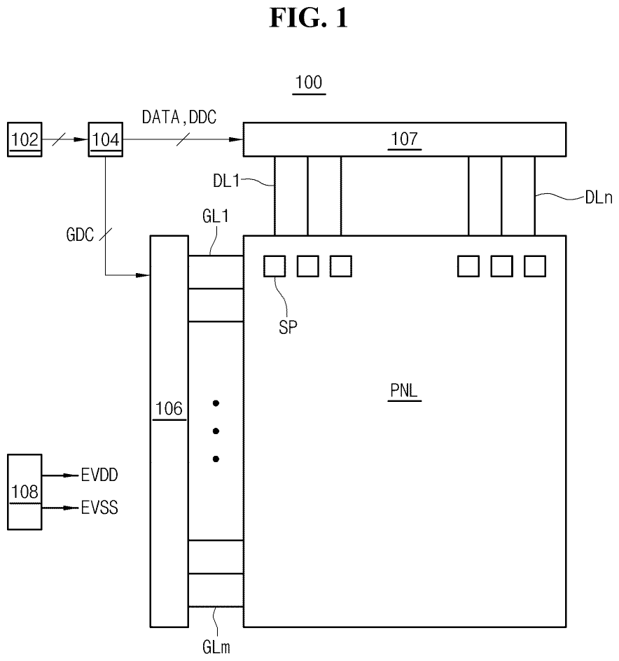

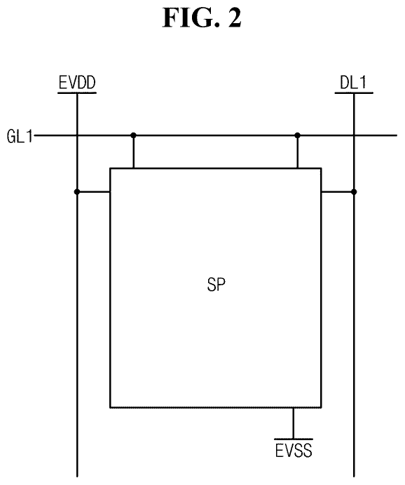

FIG. 1 illustrates a schematic block diagram of a display device in accordance with the present disclosure. FIG. 2 illustrates a schematic block diagram of a sub-pixel in the display device in accordance with the present disclosure.

Referring FIG. 1, a display device 100 can comprise an image processor 102, a timing controller 104, a gate driver 106, a data driver 107, a power supplier 108 and a display panel PNL.

The image processor 102 outputs driving signals for driving various components together with an image data supplied from outside. For example, the driving signal output form the image processor 102 can comprise, but is not limited to, a data enable signal, a vertical synchronization signal, a horizontal synchronization signal, a clock signal, and the like.

The timing controller 104 receives driving signals along with the image data from the image processor 102. The timing controller 104 generates and outputs a gate timing control signal GDC for controlling an operation timing of the gate driver 106 and a data timing control signal DDC for controlling an operation timing of the data driver 107 based on the driving signal input from the image processor 102.

The gate driver 106 outputs a scan signal to the display panel PNL in response of the gate timing control signal GDC supplied from the timing controller 104. The gate driver 106 outputs the scan signal though a plurality of gate lines GL1 to GLm (m is an integer equal to or greater than 2). In one embodiment of the present disclosure, the gate driver 106 can be shaped as an integrated circuit (IC), but is not limited thereto.

The data driver 107 outputs data voltage to the display panel PNL in response of the data timing control signal DDC input from the timing controller 104. The data driver 107 samples and latches a digital-type data signal DATA supplied from the timing controller 104 and convers the digital-type data signal DATA into analog-type data voltage based on a gamma voltage. The data driver 107 outputs the data voltage through a plurality of data lines DL1 to DLn (n is an integer equal to or greater than 2). In one embodiment of the present disclosure, the data driver 107 can be shaped as an integrated circuit (IC), but is not limited thereto.

The power supplier 108 outputs high-potential voltage VDD and low-potential voltage VSS and supplies the voltages VDD and VSS to the display panel PNL. The high-potential voltage VDD is supplied to the display panel PNL through a first power line EVDD and the low-potential voltage VSS is supplied to the display panel PNL through a second power line EVSS. Alternatively or additionally, the voltages output form the power supplier 108 can be output to the gate driver 106 and/or the data driver 107 for driving those drivers 106 and 107.

The display panel PNL display images in response to the scan signal supplied from the gate driver 106, the data voltage supplied from the data driver 107 and the power supplied from the power supplier 108.

The display panel PNL comprises a plurality of sub-pixels SPs to display an image. In one embodiment of the present disclosure, the sub-pixel SP can comprise a red (R) sub-pixel, a green (G) sub-pixel and a blue (B) sub-pixel. Alternatively, the sub-pixel SP can comprise a white (W) sub-pixel, a red (R) sub-pixel, a green (G) sub-pixel and a blue (B) sub-pixel. In one embodiment of the present disclosure, the white (W), red (R), green (G) and blue (B) sub-pixels can have a substantially same area. Alternatively, the white (W), red (R), green (G) and blue (B) sub-pixels can have different areas.

Referring to FIG. 2, each sub-pixel SP of the display panel PNL can be connected to a gate line GL1, a data line DL1, a first power line EVDD and a second power line EVSS. The numbers and driving methods of a transistor and a capacitor can be determined by configuration of the pixel circuit in the sub-pixel SP.

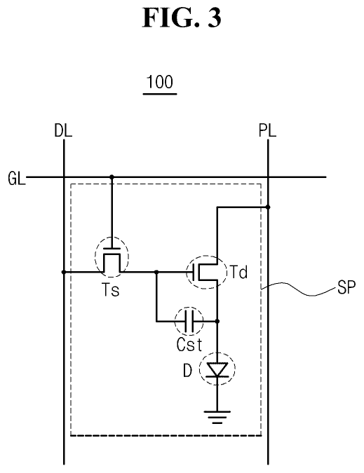

FIG. 3 illustrates a schematic circuit diagram of a sub-pixel in the display device in accordance with the present disclosure. In this example, each sub-pixel in the display device of FIG. 1 or other figures of the present application can have the sub-pixel configuration of FIG. 3.

Referring to FIG. 3, the display device 100 includes a gate line GL, a data line DL and a power line PL crossing each other to define the sub-pixel SP. A switching thin film transistor Ts, a driving thin film transistor Td, a storage capacitor Cst and a light-emitting diode D can be disposed in the sub-pixel SP.

The switching thin film transistor Ts is connected to the gate line GL and the data line DL. The driving thin film transistor Td and the storage capacitor Cst are connected between the switching thin film transistor Ts and the power line PL, and the light-emitting diode D is connected to the driving thin film transistor Td.

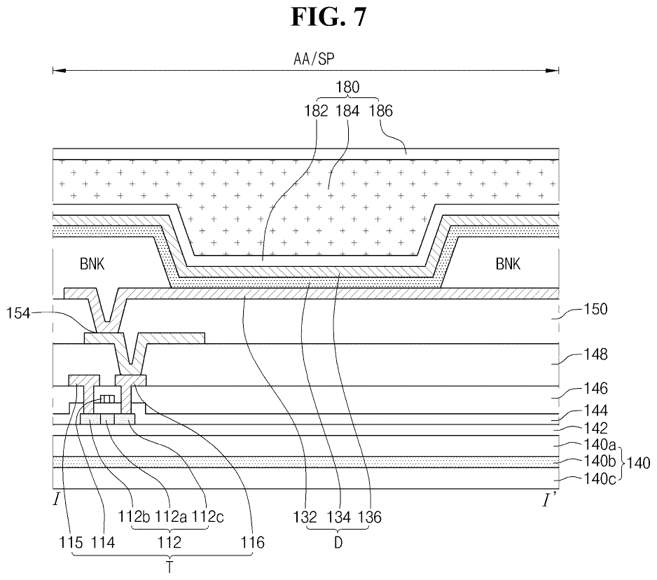

In the display device 100, when the switching thin film transistor Ts is turned on by a gate signal applied to the gate line GL, a data signal applied to the data line DL is applied a gate electrode 114 (FIG. 7) and one electrode of the storage capacitor Cst through the switching thin film transistor Ts.

The driving thin film transistor Td is turned on by the data signal applied to the gate electrode 114 so that a current proportional to the data signal is supplied from the power line PL to the light-emitting diode D through the driving thin film transistor Td. And then, the light-emitting diode D emits light having a luminance proportional to the current flowing through the driving thin film transistor Td. In this case, the storage capacitor Cst is charged with a voltage proportional to the data signal so that the voltage of the gate electrode 114 in the driving thin film transistor Td is kept constant during one frame. Therefore, the display device 100 can display a desired image.

In FIG. 3, the display device 100 includes two thin film transistors Ts and Td and one storage capacitor Cst in the sub-pixel SP. However, the display device 100 can comprise three or more thin film transistors and two or more storage capacitors.

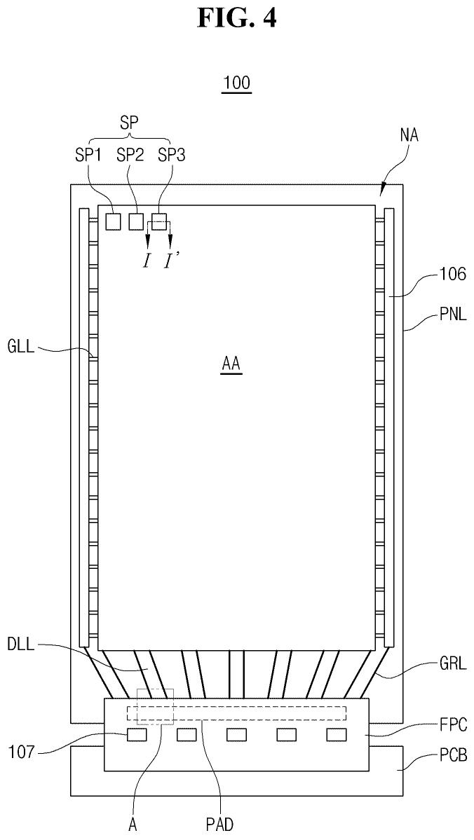

FIG. 4 illustrates a schematic plane view of a display device in accordance with one or more embodiments of the present disclosure.

Referring to FIG. 4, the display device 100 in accordance with the present disclosure includes a display area AA (or active area) where the image is displayed, and a non-display area NA (or non-active area) positioned outside of the display area AA.

A pixel P including the plurality of sub-pixels SP1, SP2 and SP3 is arranged in the display area AA. In one embodiment of the present disclosure, the sub-pixels SP1, SP2 and SP3 can be a red (R) sub-pixel, a green (G) sub-pixel and a blue (B) sub-pixel, respectively. Alternatively or additionally, the pixel P can further include a white (W) sub-pixel or can have a different sub-pixel configuration.

A plurality of gate lines and a plurality of data line can be disposed in the display area AA, and the sub-pixels SP1, SP2 and SP3 can be arranged on an area where the gate line and the data line cross. A switching element such as a thin film transistor and a display diode or element for implementing an image can be disposed in each of the sub-pixels SP1, SP2 and SP3.

The display element can include various display elements. For example, the display element can comprise, but is not limited to, an organic light-emitting display diode, a liquid crystal display device, a quantum-dot display diode, a micro LED display diode and a mini LED display diode.

The gate driver 106 that supplies the scan signal to the sub-pixels SP1, SP2 and SP3 can be placed in the non-display area NA on both sides of the display area AA. The gate driver 106 applies the scan signal to the sub-pixels SP1, SP2 and SP3 through the gate line to turn on the thin film transistors arranged in the sub-pixels SP1, SP2 and SP3.

In one embodiment of the present disclosure, the gate driver 106 can be a GIP (Gate In Panel) circuit in which a driving circuit is directly integrated on the substrate, but is not limited thereto. The gate driver 106 is connected to the gate line of the display area AA through a gate link line GLL and applies the scan signal to the gate line. In FIG. 4, the gate driver 106 is placed in the non-display area NA on both sides of the display area AA. In another embodiment, the gate driver 106 can be placed only in the non-display area NA on one side of the display area AA.

One end of a flexible circuit board FPC is attached to the end of the non-display area NA below the display area AA, and the other end of the flexible circuit board FPC is attached to a printed circuit board PCB. A plurality of data drivers 107 are arranged on the flexible circuit board FPC. The data driver 107 can be configured in the form of an integrated circuit (IC) chip and can be mounted on the flexible circuit board FPC.

In addition, a plurality of signal lines are arranged on the flexible circuit board FPC, so that signals are input from the outside to the data driver 107, and signals output from the data driver 107 are supplied to the display panel PNL. The timing controller 104 and the power supplier 108 are arranged on the printed circuit board PCB to apply various signals and voltages to the data driver 107 and the display panel PNL.

Additionally, a gate routing line GRL is arranged at the bottom of the non-display area NA below the display area AA to apply various signals to the gate driver 106.

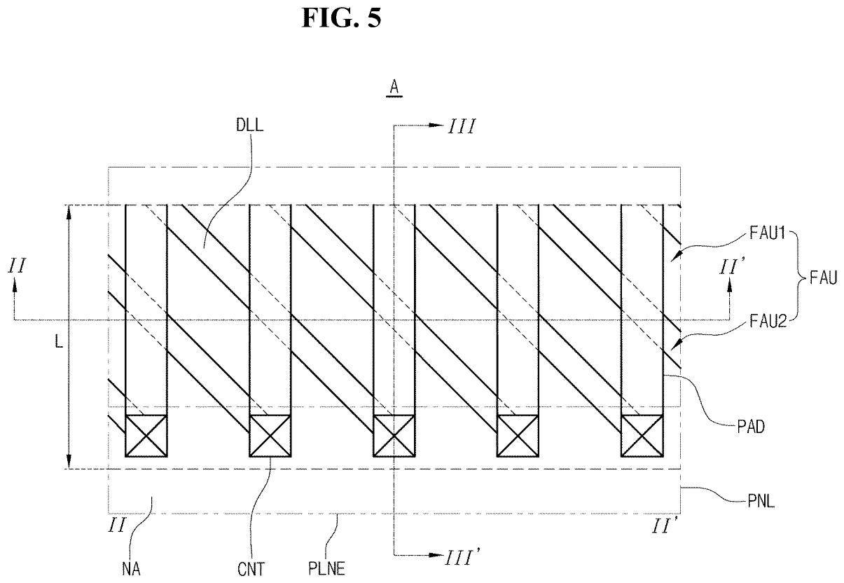

FIG. 5 illustrates an enlarged plane view of “A” region in FIG. 4 according to an example of the present disclosure.

Referring to FIG. 5, a connection area FAU where one end of the flexible circuit board FPC is attached is formed in the non-display area NA below the display area AA. The connection area FAU can be formed at a certain distance from the lower edge PNLE of the display panel PNL. In addition, the connection area FAU can be formed with a set width L.

A pad electrode PAD is arranged in the connection area FAU. The pad electrode PAD is an electrode to which the signal line of the flexible circuit board FPC is electrically connected when the flexible circuit board FPC is attached to the display panel PNL.

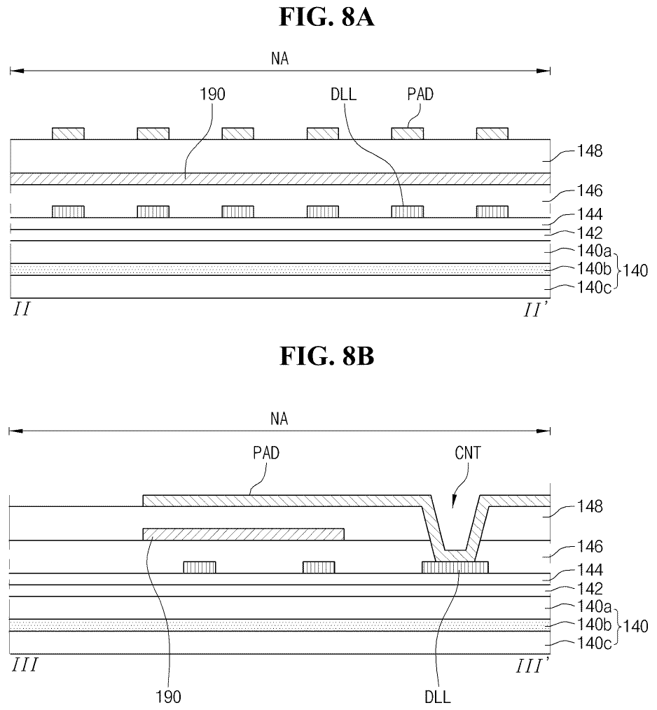

As described below, the pad electrode PAD is positioned with multiple insulating layers 146 and 148 (FIGS. 8A and 8B) between it and the data link line DLL. The pad electrode PAD can be electrically connected to the data link line DLL through a contact portion CNT. Accordingly, the data signal output from the data driver 107 mounted on the flexible circuit board FPC can be applied to the data line of the display area AA through the signal line of the flexible circuit board FPC, the pad electrode PAD, the contact portion CNT and the data link line DLL.

The upper area of the connection area FAU is a first area FAU1 adjacent to the display area AA, and the lower area of the connection area FAU is a second area FAU2 adjacent to the lower edge PNLE of the display panel PNL. The contact portion CNT between the pad electrode PAD and the data link line DLL are arranged in the second area FAU2, which is the lower area of the connection area FAU. For example, the contact portion CNT is arranged adjacent to the lower edge PNLE of the display panel PNL.

As the contact portion CNT is arranged adjacently to the lower edge PNLE of the display panel PNL, both the pad electrode PAD and the data link line DLL are arranged in the connection area FAU. In one embodiment of the present disclosure, at least a portion of the pad electrode PAD overlaps with the data link line DLL in the connection area FAU. Interference can occur between the signals flowing through the data link line DLL and the pad electrode PAD, causing signal distortion.

A shielding electrode 190 (FIG. 8B) can be arranged in the display panel PNL in order to prevent such signal distortion. In one embodiment of the present disclosure, the shielding electrode 190 can be arranged between the data link line DLL and the pad electrode PAD. In FIG. 8B, the shielding electrode 190 is arranged in the non-display area NA below the display area AA of the display panel PNL in a rectangular shape with a set width, but is not limited thereto and can be formed in various widths and shapes. For example, the shielding electrode 190 can be formed only in an area where the data link line DLL and the pad electrode PAD overlap. In this case, the area of the bezel can be minimized by arranging the contact portion CNT in the second area FAU2 adjacent to the lower edge PNLE of the display panel PNL, which will be described.

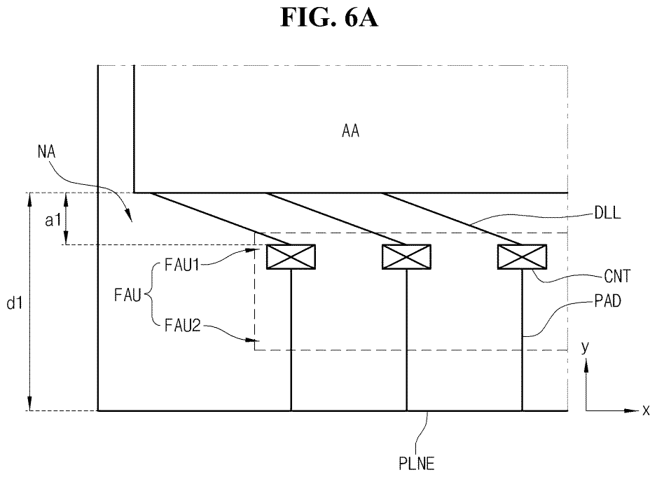

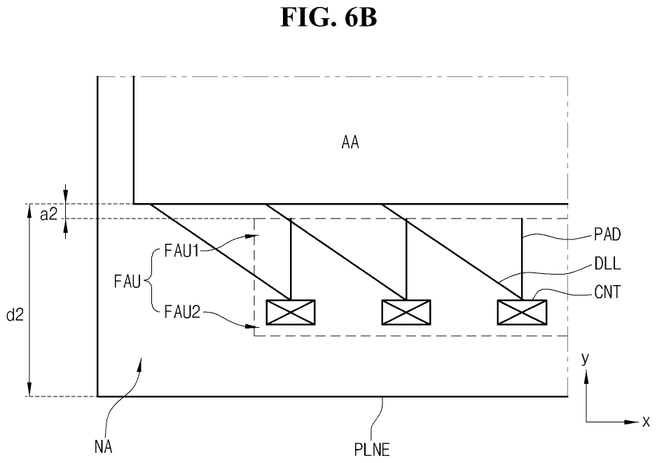

FIG. 6A illustrates a schematic display device where a contact portion is positioned on an upper area of a connection area to which a flexible circuit board is attached. FIG. 6B illustrates a schematic display device where a contact portion is positioned on a lower area of a connection area to which a flexible circuit board is attached in accordance with one or more embodiments of the present disclosure.

Referring to FIG. 6A, when the contact portion CNT is arranged in the first area FAU1 of the upper area of the connection area FAU, the data link line DLL is arranged between the contact portion CNT and the display area AA. In this case, as the width of the flexible circuit board FPC is less than the width of the display panel PNL, the area where the contact portion CNT of the pad electrode PAD, which is in contact with the signal line of the flexible circuit board FPC, is formed is much smaller than the width of the display area AA. Accordingly, the data link line DLL arranged in the central area of the display panel PNL is extended along the vertical direction (i.e., y-axis direction), the data link lines DLLs arranged in the left-right areas of the display panel PNL are extended at an inclined angle with respect to the y-axis direction. The plurality of data link lines DLLs in the area between the area where the contact portion CNT is formed and the display area AA are arranged in a fan shape.

In this case, a space for the data link line DLL to be placed is required in order for the pad electrode PAD and the data line of the display area AA to be electrically connected by the data link line DLL. For example, the pad electrode PAD in the non-display area NA should be spaced apart from the display area AA by a set distance a1 in order for the pad electrode PAD and the data line of the display area AA to be electrically connected by the data link line DLL.

On the contrary, referring to FIG. 6B, when the contact portion CNT is arranged in the second area FAU2 of the lower area of the connection area FAU, the distance a2 between the pad electrode PAD in the non-display area NA and the display area AA is reduced (a2<a1) since the connection area FAU serves as the space where the data link line DLL is arranged. Accordingly, the bezel width d2 of the display device 100 according to the present disclosure is significantly reduced (d2<d1) compared the bezel width d1 of the display device having a structure in which the contact portion CNT is arranged in the first area FAU1 of the upper area of the connection area FAU.

Hereinafter, the display device 100 in accordance with the present disclosure will be described in more detail with referring to the attached drawings. FIG. 7 illustrates a schematic cross-sectional view of the display device taken along a line I-I′ in FIG. 4 according to an example of the present disclosure. FIG. 8A illustrates a schematic cross-sectional view of the display device taken along a line II-II′ in FIG. 5. FIG. 8B illustrates a schematic cross-sectional view of the display device taken along a line III-III′ in FIG. 5 according to an example of the present disclosure.

Referring to FIGS. 7, 8A and 8B, a substrate 140 includes the display area AA and the non-display area NA. The substrate 140 can comprise a flexible material. For example, the substrate 140 can comprise a plurality of base layers 140a and 140c and an intermediate layer 140b between the base layers 140a and 140c. In FIGS. 7, 8A and 8B, the substrate 140 includes two base layers 140a and 140c and one intermediate layer 140b, but is not limited thereto. Alternatively or additionally, the substrate 140 can comprise three or more base layers and two or more intermediate layers.

Each of the base layers 140a and 140c can comprise plastics material. For example, each of the base layers 140a and 140c can comprise, but is not limited to, polyimide (PI), polymethyl methacrylate (PMMA), polyethylene terephthalate (PET), polyether sulfone (PES), polycarbonate (PC) and combinations thereof.

The intermediate layer 140b can comprise inorganic material. For example, the intermediate layer 140b can comprise, but is not limited to, silicon oxide (SiOₓ, wherein 0<x≤2) and silicon nitride (SiNₓ, wherein 0<x≤2).

When the substrate 140 includes the base layers 140a and 140c of the plastics material and the intermediate layer 140b of the inorganic material, it is possible to prevent the moisture from the outside from penetrating into the display device 100. In general, while organic materials such as plastics are vulnerable to moisture penetration, inorganic material can block the moisture penetration. In the present disclosure, moisture is prevented from penetrating into the display device 100 by arranging the intermediate layer 140b made of inorganic material between the base layers 140a and 140c made of organic material.

A buffer layer 142 can be disposed on the substrate 140. The buffer layer 142 can be disposed on the entire substrate 140 to improve adhesion between layers disposed on the substrate 140 and the substrate 140, and to block alkaline components, etc. from leaking out from the substrate 140. In addition, the buffer layer 142 can delay the diffusion of moisture or oxygen that has penetrated into the substrate 140.

In embodiment of the present disclosure, the buffer layer 142 can comprise an insulating material. For example, the buffer layer 142 can comprise, but is not limited to, an inorganic insulating material such as silicon oxide (SiOₓ, wherein 0<x≤2) and silicon nitride (SiNₓ, wherein 0<x≤2). The buffer layer 142 can have a single-layer structure or a multiple-layer structure. For example, the buffer layer 142 can have a lamination structure of a layer of silicon nitride (SiNₓ) and a layer of silicon oxide (SiOₓ). But embodiments of the present disclosure are not limited thereto. In some embodiments of the present disclosure, the buffer layer 142 can be omitted by the kinds and materials of the substrate 140 and the structure and/or the type of the thin film transistor.

A thin film transistor T is disposed on the buffer layer 142 in the display area AA. For the convenience of explanation, only the driving thin film transistor T among the various thin film transistors that can be arranged in the display area AA is illustrated in FIG. 7, but other thin film transistor such as a switching thin film transistor can be disposed. In addition, the thin film transistor with a top gate structure is illustrated in FIG. 7, the structure of the thin film transistor T is not limited thereto, and the thin film transistor T with other structures such as a bottom gate structure can be implemented.

The thin film transistor T can comprise a semiconductor layer 112 disposed on the buffer layer 142, a gate insulating layer 144 disposed on the semiconductor layer 112, a gate electrode 114 disposed on the gate insulating layer 144, an interlayer insulating layer 146 disposed on the gate electrode 114, and a source electrode 115 and a drain electrode 116 disposed on the interlayer insulating layer 146.

In one embodiment of the present disclosure, the semiconductor layer 112 can comprise a polycrystalline semiconductor. For example, the polycrystalline semiconductor can comprise, but is not limited to, low temperature poly silicon (LTPS) with beneficial mobility.

In another embodiment, the semiconductor layer 112 can comprise an oxide semiconductor. For example, the oxide semiconductor can comprise, but is not limited to, indium-gallium-zinc oxide (IGZO), indium-zinc oxide (IZO), indium-gallium-tin oxide (IGTO), indium-gallium oxide (IGO) and combinations thereof. In some embodiments of the present disclosure, the semiconductor layer 112 can comprise a channel area 112a of the central area, and a source area 112b and a drain area 112c as the doping areas on both sides of the channel areal 112a.

In one embodiment of the present disclosure, the gate insulating layer 144 can be arranged in the display area AA and the non-display area NA. In another embodiment, the gate insulating layer 144 can be arranged only in the display area AA. For example, the gate insulating layer 144 can comprise an inorganic insulating material such as silicon oxide (SiOₓ, wherein 0<x≤2) and silicon nitride (SiNₓ, wherein 0<x≤2). The gate insulating layer 144 can have a single-layer structure or a multiple-layer structure. But embodiments of the present disclosure are not limited thereto.

In one embodiment of the present disclosure, the interlayer insulating layer 146 can be arranged in the display area AA and the non-display area NA. In another embodiment, the interlayer insulating layer 146 can be arranged only in the display area AA. For example, the interlayer insulation layer 146 can comprise, but is not limited to, an organic material such as photo-acryl or an inorganic insulating material such as silicon oxide (SiOₓ, wherein 0<x≤2) and silicon nitride (SiNₓ, wherein 0<x≤2). The interlayer insulating layer 146 can have a single-layer structure or a multiple-layer structure. In another embodiment, the interlayer insulating layer 146 can have a multi-layer structure with at least one organic layer and at least one inorganic layer. But embodiments of the present disclosure are not limited thereto.

In one embodiment of the present disclosure, each of the source electrode 115 and the drain electrode 116 can comprise, but is not limited to, molybdenum (Mo), aluminum (Al), chrome (Cr), gold (Au), titanium (Ti), nickel (Ni), neodymium (Nd), copper (Cu), combinations thereof, or alloys thereof. Each of the source electrode 115 and the drain electrode 116 can have a single-layer structure or a multi-layer structure. But embodiments of the present disclosure are not limited thereto. The source electrode 115 and the drain electrode 116 can be contacted to the source area 112b and the drain area 112c of the semiconductor layer 112, respectively, through contact holes formed in the gate insulating layer 144 and/or the interlayer insulating layer 146.

In another embodiment, a bottom shield metal layer can be disposed between the substrate 140 and the semiconductor layer 112. The bottom shield metal layer can be arranged to minimize the back channel phenomenon caused by charges trapped in the substrate 140 and to prevent afterimages or performance degradation of the transistor. For example, the bottom shield metal layer can comprise, but is not limited to, titanium (Ti), molybdenum (Mo) and alloys thereof. The bottom shield metal layer can have a single-layer structure or a multi-layer structure.

A first planarization layer 148 is disposed on the substrate 140 where the thin film transistor T is disposed. In one embodiment of the present disclosure, the first planarization layer 148 can comprise, but is not limited to, an organic material such as photo-acryl. In another embodiment, the first planarization layer 148 can have a multi-layer structure with at least one inorganic layer and at least one organic layer.

A connection pattern 154 is disposed on the first planarization layer 148. The connection pattern 154 can be electrically connected to the drain electrode 116 of the thin film transistor T through a contact hole formed in the first planarization layer 148. For example, the connection pattern 154 can comprise a metallic component.

A second planarization layer 150 is disposed on the first planarization layer 148 where the connection pattern 154 is disposed. In one embodiment of the present disclosure, the second planarization layer 150 can comprise, but is not limited to, an organic material such as photo-acryl. In another embodiment, the second planarization layer 150 can have a multi-layer structure with at least one inorganic layer and at least one organic layer. In one embodiment of the present disclosure, the second planarization layer 150 can comprise a same material as the first planarization layer 148. In another embodiment, the second planarization layer 150 can comprise a different material from the first planarization layer 148.

It is possible to arrange various electrodes and lines between the first planarization layer 148 and the second planarization layer 150 by arranging two or more planarization layers 148 and 150. In this case, since the electrodes can be arranged vertically, the area due to the electrodes and lines in the sub-pixels can be reduced. Therefore, it is possible to reduce the area of the sub-pixels and to manufacture the display device 100 with a high resolution.

A light-emitting diode or element D is disposed on the second planarization layer 150 in the display area AA. The light-emitting diode D can comprise a first electrode 132, an emissive layer 134 and a second electrode 136 each of which disposed sequentially on the second planarization layer 150.

The first electrode 132 is disposed on the second planarization layer 150. The first electrode 132 can be electrically connected to the connection pattern 154 through a contact hole formed in the second planarization layer 150. In other words, the first electrode 132 can be electrically connected to the drain electrode 116 of the thin film transistor T through the connection pattern 154.

For example, the first electrode 132 can comprise, but is not limited to, a metallic component such as silver (Ag), aluminum (Al), molybdenum (Mo), tungsten (W), chrome (Cr), combinations thereof or alloys thereof. In another embodiment, the first electrode 132 can comprise, but is not limited to, transparent metal oxide layer such as indium-tin oxide (ITO) and/or indium-zinc oxide (IZO).

In one embodiment of the present disclosure, when the display device 100 is a top-emission type, the first electrode 132 can further comprise an opaque conductive material acting as a reflection electrode. In another embodiment, when the display device 100 is a bottom-emission type, the first electrode 132 can be disposed using the transparent conductive material such as ITO and/or IZO.

A bank layer BNK is disposed on the second planarization layer 150 at the boundary of each sub-pixel. The bank layer BNK can be a kind of a partitioned wall defining each sub-pixel. The bank layer BNK partitions each sub-pixel and can prevent light of a specific color output from adjacent sub-pixels from being mixed and output.

For example, the bank layer BNK can comprise, but is not limited to, an inorganic material such as silicon oxide (SiOₓ, wherein 0<x≤2) and silicon nitride (SiNₓ, wherein 0<x≤2), an organic material such as an acryl-containing resin, an epoxy-containing resin, a phenol-containing resin, a polyamide-containing resins and/or a polyimide-containing resin, a photo-sensitive agent containing a black pigment and/or dye, and combinations thereof.

The emissive layer 134 can be arranged on the first electrode 132, an inclined surface of the bank layer BNK and on the bank layer BNK in the display area AA, and extend to the non-display area NA.

In one embodiment of the present disclosure, the emissive layer 134 can comprise, but is not limited to, a red emissive layer emitting red color and disposed in the red sub-pixel, a green emissive layer emitting green color and disposed in the green sub-pixel and a blue emissive layer emitting blue color and disposed in the blue sub-pixel. For example, the emissive layer 134 can comprise, but is not limited to, an organic emissive layer, or an inorganic emissive layer such as a nano-sized material layer, quantum dots, a micro LED emissive layer or a mini LED emissive layer.

In one embodiment of the present disclosure, the emissive layer 134 can comprise an emitting material layer. In another embodiment, the emissive layer 134 can further comprise a hole injection layer, a hole transport layer, and/or an electron blocking layer disposed between the first electrode 132 and the emitting material layer, and an electron injection layer, an electron transport layer and/or a hole blocking layer disposed between the emitting material layer and the second electrode 136.

The second electrode 136 is disposed on the emissive layer 134. In one embodiment of the present disclosure, the second electrode 136 can have a single-layer structure or a multi-layer structure with a metallic component or alloys thereof. In another embodiment, the second electrode 136 can comprise a transparent metal oxide such as ITO and/or IZO. But embodiments of the present disclosure are not limited thereto.

In one embodiment of the present disclosure, when the display device 100 is a top-emission type, the second electrode 136 can be arranged using the transparent or semi-transparent conductive material. For example, the second electrode 136 can comprise, but is not limited to, an alloy such as LiF/Al, CsF/Al, Mg:Ag, Ca/Ag, Ca:Ag, LiF/Mg:Ag, LiF/Ca/Ag, LiF/Ca:Ag and combinations thereof.

In another embodiment, when the display device 100 is a bottom-emission type, the second electrode 136 can be arranged using an opaque conductive material. For example, the second electrode 136 can comprise, but is not limited to, silver (Ag), aluminum (Al), gold (Au), molybdenum (Mo), tungsten (W), chrome (Cr) and/or alloys thereof.

In another embodiment, the light-emitting diode D can have a tandem structure. The tandem structure includes a plurality of emitting parts and at least one charge generation layers disposed between the emitting parts. The charge generation layer is intended to connecting the plural emitting parts. In one embodiment of the present disclosure, a plurality of charge generation layers including a first charge generation layer and a second charge generation layer can be disposed. In one embodiment of the present disclosure, the charge generation layer can include an N-type charge generation layer and a P-type charge generation layer. For example, the charge generation layer can comprise, but is not limited to, an organic layer doped with alkali metal such as Li, Na, K and/or Cs and/or alkaline earth metal such as Mg, Sr, Ba and/or Ra.

An encapsulation layer 180 is disposed in the display area AA and the non-display area NA to encapsulate the light-emitting diode D. When the light-emitting diode D is exposed to moisture or oxygen, a pixel shrinkage phenomenon in which the light emission area shrinks or a defect in which a dark spot is formed within the light emission area can occur. In addition, the moisture or oxygen can oxidize the electrode made of the metallic component. The encapsulation layer 180 blocks the penetration of moisture and oxygen from the outside to prevent defects in the light-emitting diode D and various electrodes.

In one embodiment of the present disclosure, the encapsulation layer 180 can comprise, but is not limited to, a first encapsulation layer 182, a second encapsulation layer 184 and a third encapsulation layer 186. In another embodiment, the encapsulation layer 180 can comprise two layers or four or more layers.

In one embodiment of the present disclosure, each of the first encapsulation layer 182 and the third encapsulation layer 186 can comprise an inorganic material such as silicon oxide (SiOₓ, wherein 0<x≤2) and silicon nitride (SiNₓ, wherein 0<x≤2). Each of the first encapsulation layer 182 and the third encapsulation layer 186 can have a single-layer structure or a multi-layer structure. In another embodiment, each of the first encapsulation layer 182 and the third encapsulation layer 186 can further comprise at least one organic layer disposed between the inorganic layers. The second encapsulation layer 184 can comprise an epoxy-containing resin. But the embodiments of the present disclosure are not limited thereto.

A touch member can be disposed on the encapsulation layer 180. The touch member can be disposed in the display area AA and sense the touch input. The touch member can sense outer touch information using user's finger or a touch pen.

The plurality of data link lines DLLs spaced apart from each other with a set interval are disposed on the gate insulating layer 144 in the non-display area NA. For example, the data link line DLL can be arranged, but is not limited to, using a same metallic component as the gate electrode 114 of the thin film transistor T by a same process.

The plural pad electrodes PADs spaced apart from each other with a set interval are disposed on the first planarization layer 148. For example, the pad electrode PAD can be arranged, but is not limited to, using a same metallic component as the connection pattern 154 by a same process.

When the display panel PNL is manufactured, the pad electrode PAD is exposed to the outside, and when the flexible circuit board FPC is attached to the display panel PNL, the signal line of the flexible circuit board FPC comes into contact with the exposed pad electrode PAD, so that the display panel PNL is electrically connected to the flexible circuit board FPC.

The interlayer insulating layer 146 and the first planarization layer 148 are disposed between the data link line DLL and the pad electrode PAD. The data link line DLL is electrically connected to the pad electrode PAD through the contact portion CNT, i.e., the contact holes formed in the interlayer insulating layer 146 and the first planarization layer 148.

The shielding electrode 190 is arranged on the interlayer insulating layer 146 between the data link line DLL and the pad electrode PAD, thereby preventing interference between the data link line DLL and the pad electrode PAD, and preventing distortion of the signal of the data link line DLL and the pad electrode PAD.

In another embodiment, the data link line DLL, the pad electrode PAD and the shielding electrode 190 can be arranged in various layers. For example, the data link line DLL can be arranged on the interlayer insulating layer 146. In this case, the data link line DLL can be formed using a same metallic component as the source electrode 115 and the drain electrode 116 of the thin film transistor T through a same process. In another embodiment, the first planarization layer 148 is formed as a two-layer structure of upper and lower layers. In this case, the data link layer DLL is arranged under the lower layer of the first planarization layer 148, the shielding electrode 190 is arranged on the lower layer of the first planarization layer 148, and the pad electrode PAD is arranged on the upper layer of the first planarization layer 148. In other words, the data link line DLL and the shielding electrode 190 are arranged with the lower layer of the first planarization layer 148 between them, and the shielding electrode 190 and the pad electrode PAD are arranged with the upper layer of the first planarization layer 148 between them.

As described in detail above, the contact portion CNT where the data link line DLL and the pad electrode PAD are connected is placed in the second area FAU2 adjacent to the lower edge PNLE of the display panel PNL. Since the area of the non-display area NA below the display panel PNL can be minimized, it is possible to implement narrow bezel.

It will be apparent to those skilled in the art that various modifications and variations can be made in the present disclosure without departing from the scope of the disclosure. Thus, it is intended that the present disclosure cover the modifications and variations of the present disclosure provided they come within the scope of the appended claims.

What is claimed is:

1. A display device, comprising:
a display panel including a display area and a non-display area positioned outside of the display area;
a connection area disposed in the non-display area of the display panel and a flexible circuit board attached to the non-display area of the display panel;
a data link line disposed in the non-display area of the display panel and connected to a data line of the display area; and
a pad electrode disposed in the non-display area of the display panel and connected electrically to a signal line of the flexible circuit board,
wherein the connection area includes a first area adjacent to the display area and a second area disposed between the first area and an edge of the display panel, and
wherein the data link line and the pad electrode are connected to the second area of the connection area.

2. The display device of claim 1, wherein at least a portion of the data link line is positioned to overlap with the pad electrode.

3. The display device of claim 2, further comprising a shielding electrode disposed between the data link line and the pad electrode.

4. The display device of claim 2, wherein the data link line is connected electrically to the pad electrode through a contact portion.

5. The display device of claim 4, wherein the contact portion is disposed between the data link line and the pad electrode, and the edge of the display panel.

6. The display device of claim 4, further comprising a thin film transistor and a light-emitting diode that are disposed in each of a plurality of sub-pixels in the display area.

7. The display device of claim 6, wherein the thin film transistor comprises:
a semiconductor layer disposed on a substrate;
a gate insulating layer disposed on the semiconductor layer;
a gate electrode disposed on the gate insulating layer;
an interlayer insulating layer disposed on the gate electrode; and
a source electrode and a drain electrode disposed on the interlayer insulating layer.

8. The display device of claim 7, further comprising:
a plurality of insulating layers disposed on the thin film transistor; and
a connecting pattern disposed on the plurality of insulating layers and connecting electrically the thin film transistor to the light-emitting diode.

9. The display device of claim 8, wherein the light-emitting diode comprises:
a first electrode connected electrically to the connecting pattern;
a second electrode facing the first electrode; and
an emissive layer disposed between the first electrode and the second electrode.

10. The display device of claim 8, further comprising a shielding electrode disposed between the data link line and the pad electrode,
wherein the data link line comprises a same material as the gate electrode, the shielding electrode comprises a same material as the source electrode and the drain electrode, and the pad electrode comprises a same material as the connecting pattern.

11. The display device of claim 8, wherein the contact portion is a contact hole in the plurality of insulating layers.

12. A display device, comprising:
a display panel including a display area and a non-display area positioned outside of the display area;
a flexible circuit board attached to the non-display area of the display panel;
a data link line disposed in the non-display area of the display panel and connected to a data line of the display area; and
a pad electrode disposed in the non-display area of the display panel and connected electrically to a signal line of the flexible circuit board,
wherein the data link line is extended to an inside of the flexible circuit board, and
wherein at least a portion of the data link line is positioned to overlap with the pad electrode with an insulating layer disposed between the data link line and the pad electrode.

13. The display device of claim 12, wherein data link line is connected electrically to the pad electrode though a contact portion on the insulating layer.

14. The display device of claim 13, further comprising a shielding electrode disposed between the data link line and the pad electrode.

15. The display device of claim 14, further comprising a thin film transistor and a light-emitting diode that are disposed in each of a plurality of sub-pixels in the display area.

16. The display device of claim 15, wherein the thin film transistor comprises:
a semiconductor layer disposed on a substrate;
a gate insulating layer disposed on the semiconductor layer;
a gate electrode disposed on the gate insulating layer;
an interlayer insulating layer disposed on the gate electrode; and
a source electrode and a drain electrode disposed on the interlayer insulating layer.

17. The display device of claim 16, further comprising:
a plurality of insulating layers disposed on the thin film transistor; and
a connecting pattern disposed on the plurality of insulating layers and connecting electrically the thin film transistor to the light-emitting diode.

18. The display device of claim 17, wherein the light-emitting diode comprises:
a first electrode connected electrically to the connecting pattern;
a second electrode facing the first electrode; and
an emissive layer disposed between the first electrode and the second electrode.

19. The display device of claim 17, wherein the data link line comprises a same material as the gate electrode, the shielding electrode comprises a same material as the source electrode and the drain electrode, and the pad electrode comprises a same material as the connecting pattern.

20. The display device of claim 17, wherein the contact portion is a contact hole in the plurality of insulating layers.
